(19) United States
(12) Patent Application Publication
(10) Pub. No.: US 2002/0022407 A1
(43) Pub. Date: Feb. 21, 2002

(54) METHOD AND STRUCTURE FOR TUNING THE IMPEDANCE OF ELECTRICAL TERMINALS

(76) Inventors: TOSHIHIRO NIITSU, YOKOHAMA-SHI (JP); STEPHEN A. SAMPSON, DOWNERS GROVE, IL (US); DANIEL DAWIEDCZYK, LISLE, IL (US); DAVID L. BRUNKER, NAPERVILLE, IL (US); AUGUSTO PANELLA, NAPERVILLE, IL (US); MICHAEL CHEONG, NAPERVILLE, IL (US)

Correspondence Address: JAMES C PASCHALL, MOLEX INCORPORATED, 2222 WELLINGTON COURT, LISLE, IL, 60532

(21) Appl. No.: 09/078,054

(22) Filed: May 13, 1998

(51) Int. Cl. H05K 1/00

(52) U.S. Cl. 439/676

(57) ABSTRACT

A method and structure of an electrical connector is provided for tuning the impedance of the terminals in the connector. The connector includes a dielectric housing having a plurality of terminal-receiving passages. A plurality of terminals are shaped from sheet metal material, with each terminal having a contact portion at one end and a terminating portion at an opposite end. The contact portion has a contact area which engages a mating terminal of a complementary mating connecting device. The contact portion, except for the contact thereof, or the tail portion, is selectively trimmed to a given size to vary the plate area of the contact portion or the tail portion to adjust the impedance of the terminal.

### FIELD OF THE INVENTION

This invention generally relates to the art of electrical connectors and, particularly, to a method and structure for controlling the impedance in electrical connectors by controlling the impedance of the terminals of the connectors.

### BACKGROUND OF THE INVENTION

In high speed electronic equipment, it is desirable that all components of an interconnection path be optimized for signal transmission characteristics, otherwise the integrity of the system will be impaired or degraded. Such characteristics include risetime degradation or system bandwidth, crosstalk, impedance control and propagation delay. Ideally, an electrical connector would have little or no effect on these characteristics of the interconnection system. In other words, the system would function as if circuitry ran through the interconnection without any effect on the system. However, such an ideal connector is impractical or impossible, and continuous efforts are made to develop electrical connectors which have as little effect on the system as possible.

Impedance and inductance control are concerns in designing an ideal connector. This is particularly true in electrical connectors for high speed electronic equipment, i.e., involving high frequencies. An example of one such connector is a board-mounted connector adapted for mounting on a printed circuit board and for mating with a complementary second connector. The connector includes a dielectric housing in which a plurality of terminals are mounted. Each terminal includes a contact portion, such as a contact blade, and a terminating portion, such as a terminal tail.

One exemplary obstacle to providing a consistent impedance across an electrical connection occurs when contact portions of terminals are mounted in a spaced-apart relationship in the dielectric housing of an electrical connector. The contact portions of terminals typically have a broad plate area relative to the rest of the terminal to assure adequate and reliable contact. The contact portions which are separated by a dielectric increase the capacitance of the terminals at the contact portions. Because impedance is inversely related to capacitance, the increase in capacitance causes an impedance drop in the terminals, thereby greatly disrupting the characteristic impedance through the overall electrical system.

This phenomena is illustrated in FIG. 22 in which impedance (Z) is plotted over distance along a terminal in a connector to provide an impedance curve for a conventional terminal. Zₒ is the average or characteristic impedance of the terminal over the distance of the terminal. The dip at Zₘᵢₙ is the lowest impedance exhibited over the terminal at the contact portion. The greater the capacitance increase at the contact portion, the greater the impedance drop with respect to the characteristic impedance Z_{O} and the greater the connector affects the electrical performance of the electrical system. Conversely, the peak at Zₘₐₓ represents the increased impedance of the tail portion at the end of the terminal which has a smaller plate area relative to the contact portion.

The invention is directed to a method and structure for tuning the impedance of an electrical connector, such as the connector described above, so as to adjust the impedance of the terminal and/or to minimize the range of deviation from the characteristic impedance of the system. The invention is specifically directed to tuning the connector by trimming or removing a section of the terminals of the connector.

### SUMMARY OF THE INVENTION

An object, therefore, of the invention is to provide a new and improved method and structure for tuning the impedance of an electrical connector by selectively trimming a section of the terminals of the connector.

In the exemplary embodiment of the invention, generally, the connector includes a dielectric housing having a plurality of terminals mounted in the housing. Each terminal includes a contact portion at one end thereof and a terminating portion at an opposite end thereof. Each terminal has a contact area for mating to a respective terminal of a complementary connector to comprise a mated terminal pair.

The invention contemplates a method and structure in which a desired impedance is determined for each terminal in the connector. The contact area of the contact portion of each terminal is determined. The contact portion, except for the contact area thereof, is selectively trimmed to a given size to reduce the plate area of the contact portion according to the determination of the desired impedance of the terminals. By reducing the plate area of the contact portion, the capacitance at the contact portion of the terminal is reduced to increase the impedance Z_{mIn} at the contact portion, thereby increasing the characteristic or average impedance Z_{O} of the terminal. This procedure also has the result of diminishing the range of deviation of the impedance from the characteristic or average impedance Z_{O} for the terminal. By increasing Zₘᵢₙ, Z_{O} is increased and brought closer to Zₘₐₓ which is determined by the terminal tail.

As disclosed herein, the contact area of the contact portion of each terminal is generally centrally located between side edges of the contact portion. All or part of the side edges may be trimmed to adjust the impedance or, alternatively, apertures or recess may be formed in the contact portion on opposite sides of the contact area. Still further, the contact portion defines a front end of the terminal, and the front end may be trimmed to vary the impedance. Furthermore, a rear section of the contact portion may also be trimmed to vary the impedance. Preferably, the terminals are formed by stamping the terminals from sheet metal material, and the contact portions can be trimmed during the stamping operation.

The invention also contemplates selectively trimming the tail portion of the terminal to adjust the plate area of the tail portion. By reducing the plate area of the tail portion, the capacitance is decreased and the impedance Zₘₐₓ of the terminal at the tail portion is increased, and the deviation of the impedance at the contacting interface area is increased thereby increasing the characteristic impedance Z_{O}. By increasing the impedance Zₘₐₓ at the tail portion, relative to the characteristic impedance Z_{O} and Zₘᵢₙ, the range of deviation between Zₘₐₓ and Zₘᵢₙ is expanded.

This invention also contemplates adding plate area to the tail portion to adjust the impedance. By enlarging the plate area of the tail portion, the capacitance of the tail portion is increased and impedance Zₘₐₓ at the tail portion is decreased to decrease the characteristic impedance Z_{o.} By reducing the impedance Zₘₐₓ at the tail portion relative to Z_{O} and Zₘᵢₙ, the range of deviation between Zₘₐₓ and Zₘᵢₙ is contracted along the length of the terminal.

Another embodiment of the invention contemplates a terminal having a drive shoulder between the contact portion and the terminating portion of the terminal, to facilitate inserting the terminal into its respective terminal-receiving passage in the connector housing. The drive shoulder is selectively located at a given position longitudinally of the terminal to vary the relative plate areas of the contact portion and the terminating portion as necessary to achieve a desired impedance in the terminal and/or minimize the deviation of the impedance from the characteristic impedance of the electrical system.

Other objects, features and advantages of the invention will be apparent from the following detailed description taken in connection with the accompanying drawings.

### BRIEF DESCRIPTION OF THE DRAWINGS

The features of this invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIG. 1 is a perspective view of one type of electrical connector assembly with which the invention is applicable;

FIG. 2 is a top plan view of the board-mounted connector of the assembly in FIG. 1;

FIG. 3 is a side elevational view of the board-mounted connector;

FIG. 4 is an end elevational view of the board-mounted connector, looking at the mating end thereof;

FIG. 5 is a vertical section, on an enlarged scale, taken generally along line 5-5 of FIG. 4 without the shield;

FIG. 6 is a horizontal section taken generally along line 6-6 of FIG. 5;

FIG. 7 is a plan view of a conventional terminal for mounting in the connector of FIG. 1, still in an intermediate form and connected to a carrier strip during manufacture;

FIG. 8 is a side elevational view of the conventional terminal of FIG. 7;

FIG. 9 is a side elevational view of the conventional terminal of FIGS. 7 and 8, after the terminal is formed to its ultimate configuration;

FIG. 10 is an enlarged sectional view of the terminal of FIG. 7 mated with the terminal of the complementary connector of FIG. 1;

FIG. 11 is a fragmented plan view of the contact portion of the conventional terminal;

FIG. 12 is a fragmented plan view of a terminal for mounting in the connector of FIG. 1, with the contact portion selectively trimmed to a particular configuration in accordance with one embodiment of the present invention;

FIG. 13 is a fragmented plan view of a terminal for mounting in the connector of FIG. 1 with the contact portion trimmed to an alternative configuration in accordance with an alternative embodiment of the present invention;

FIG. 14 is a fragmented plan view of a terminal for mounting in the connector of FIG. 1 with entire side edges of the contact portion trimmed in accordance with an additional embodiment of the present invention;

FIG. 15 is a fragmented plan view of a terminal for mounting in the connector of FIG. 1 with entire side edges of the contact portion trimmed in accordance with an additional embodiment of the present invention;

FIG. 16 is a fragmented plan view of a terminal for mounting in the connector of FIG. 1 with the contact portion selectively trimmed to a particular configuration in accordance with a further embodiment of the present invention;

FIG. 17 is a plan view of a terminal for mounting on the connector of FIG. 1, but with a wider tail portion than that of the conventional terminal of FIG. 7;

FIG. 18 is a plan view of a terminal for mounting on the connector in FIG. 1, but with sections added to the tail portion;

FIG. 19 is a plan view of a terminal for the mounting on the connector of FIG. 1, but with a more narrow tail portion than that of the terminal in FIG. 7;

FIG. 20 is a plan view of a terminal for the mounting on the connection in Figure, but with the drive shoulder of the terminal at a different location than that of the terminal in FIG. 7;

FIG. 21 is a vertical section view of the connector of FIG. 5 but mounting the terminal of FIG. 20;

FIG. 22 is a graph plotting impedance as a function of time or distance of a terminal.

### DETAILED DESCRIPTION OF THE PREFERRED RMBODIMENTS

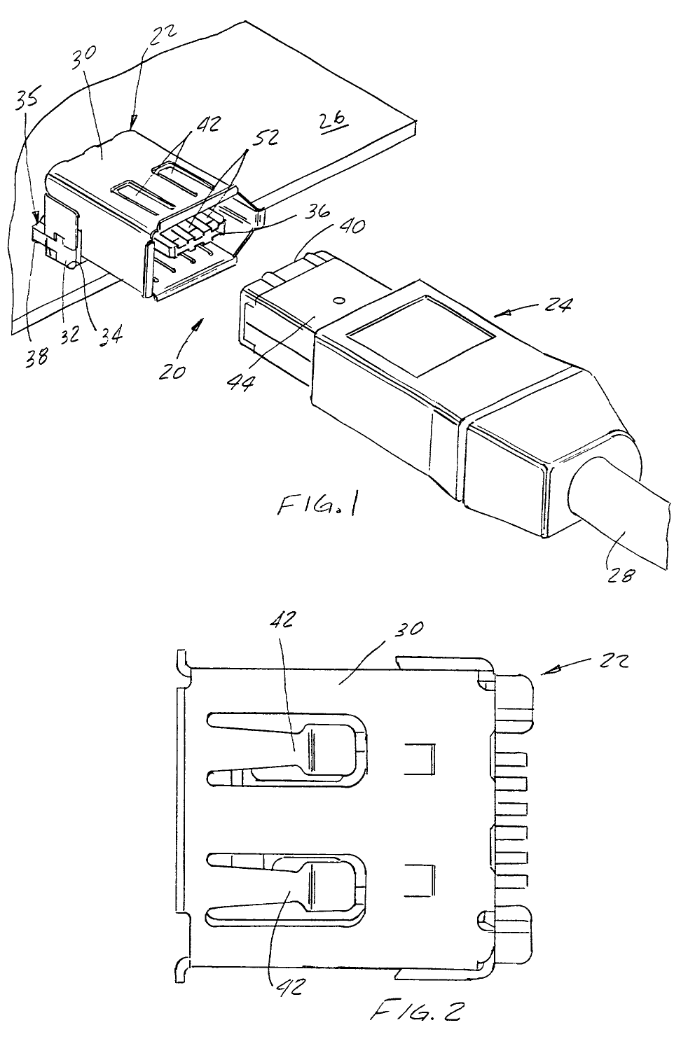

Referring to the drawings in greater detail, and first to FIG. 1, the invention is embodied in an electrical connector assembly, generally designated 20, which includes a first or board-mounted connector, generally designated 22, and a second or mating connector, generally designated 24. Board-mounted connector 22 is mounted on the top surface of a printed circuit board 26, and mating connector 24 is terminated to a multi-conductor electrical cable 28. Mating connector 24 is a conventional connector and will not be described in detail herein except to state that the connector mounts a plurality of terminals 58 which are terminated to the conductors of cable 28 and which mate with the terminals of board-mounted connector 22. The terminals 52 shown in FIGS. 1-11 of the connector 22 are initially described as conventional terminals to highlight the invention.

Referring to FIGS. 2-6 in conjunction with FIG. 1, board-mounted connector 22 is a shielded connector and includes an outer box-like shield 30 which is a one-piece structure stamped and formed of sheet metal material. The shield has integral feet portions 32 for insertion into appropriate holes 34 in the printed circuit board. The feet portions may be connected to appropriate ground traces on the printed circuit board. A dielectric housing or insert 35 is mounted within shield 30 and includes a forwardly projecting tongue or mating portion 36. As best seen in FIGS. 5 and 6, in which the housing 35 of board mounted connector 22 is shown without shield 30, a plurality of terminal-receiving passages 50 extend from a rear of the housing 35 to a front of the mating portion 36, both above and below the mating portion 36. At the rear of the housing 35 the passages 50 comprise a bore 50a. On the mating portion 36, the passages comprise a floor 51 bounded by lateral walls 53. The passages 50 are exposed between lateral walls 53 at the mating portion 36. A step 51a is provided in the floor 51 at a front end of the mating portion 36. The dielectric insert is unitarily molded of plastic material or the like and has a pair of board-mounting posts 38 for insertion into appropriate mounting holes in the printed circuit board.

The shield 30 is hollow for receiving a mating plug end 40 of second connector 24, and the plug end of the second connector has a socket for receiving forwardly projecting mating portion 36 of the dielectric insert of board-mounted connector 22. When the connectors are mated, a plurality of inwardly biased, cantilevered grounding arms 42 of shield 30 of board-mounting connector 22 make positive engagement with a circumferential shield 44 (FIG. 1) of mating connector 24.

The dielectric housing or insert 35 of board-mounted connector 22 is shown in FIGS. 5 and 6 without shield 30 to facilitate an illustration of the mounting of a plurality of terminals, generally designated 46, on the housing. The conventional terminals include contact portions 52 which are mounted in terminal-receiving passages 50 of the dielectric housing or insert 35. The contact portion 52 includes a body portion 48 disposed in the bore 50a to retain the terminal 46 in the passage 50. The contact ends or portions 52 are disposed in vertical alignment above and below the forwardly projecting mating portion 36 of the housing. Each conventional terminal includes a terminating end or tail portion 54 which projects out of a mouth 49 of the terminal-receiving passage at the rear of the housing, with the tail portion terminating in a foot 56 which is connected, such as by soldering, to an appropriate circuit trace on printed circuit board 26.

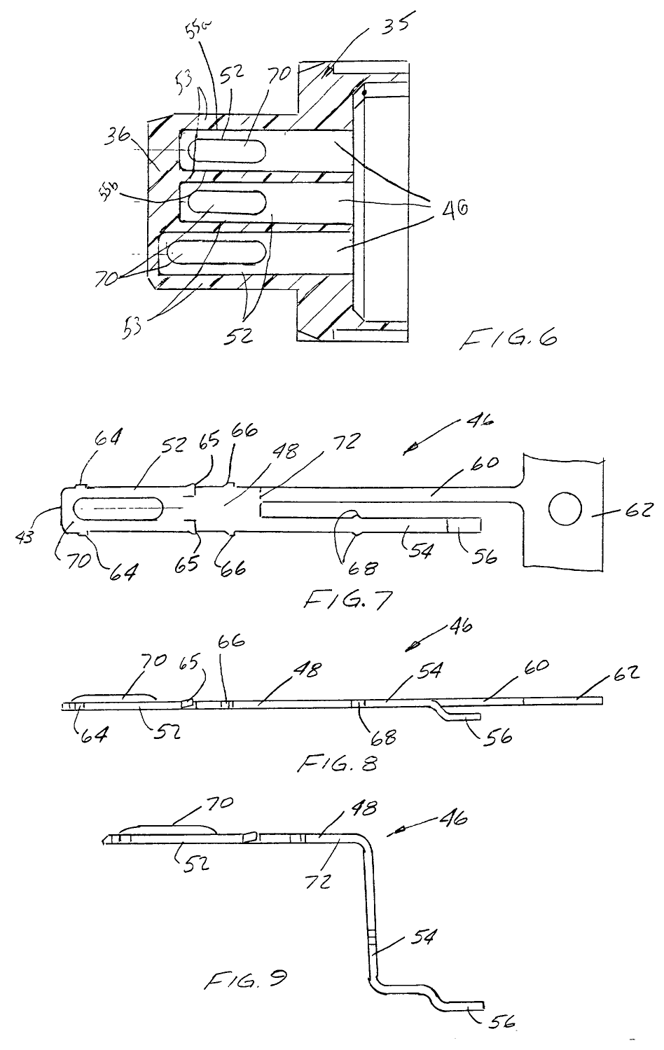

FIGS. 7 and 8 show one of the conventional terminals 46 in intermediate form after the terminal is stamped and partially formed from conductive sheet metal material, but with the terminal still connected by a web 60 to a carrier strip 62 during manufacture. It can be seen that contact portion 52 and tail portion 54 are stamped at opposite ends of the terminal 46 and the contact portion 52 is wider than the tail portion 54. The contact portion 52 includes a forward tip 43. Foot portion 56 at the distal end of tail portion 54 is offset from the tail portion during the stamping and forming operation, as seen in FIG. 8. Skiving teeth 64 for contact portion 52, teeth 65, 66 for body portion 48 and teeth 68 for tail portion 54 are formed during the stamping operation, for skiving into the plastic material of housing 35 to facilitate securing the terminal and its respective portions in the housing. Teeth 64, 65 and 66 skive into lateral walls 53 of terminal passages 50. Teeth 65 are cut on two edges from body portion 48 and are upwardly deformed. Upon insertion of the terminal 46 into terminal passages 50, teeth deflect to provide additional retention. First and second lateral edges 55a and 55b of terminals 46 are disposed at lateral walls 53 when mounted in terminal passages 50. Although the terminals 46 are described herein to be mounted in the housing 35 by insertion into terminal passageways, the terminals 46 of the present invention may be mounted in the housing 35 or a housing of a different connector to which the invention is applicable by insert-molding.

At this point, it should be noted that contact portion 52 of each conventional terminal 46 has an elongated raised boss 70 formed during the stamping and forming operation of the terminal. This raised boss defines the contact area of the contact portion which engages a complementary contact of one of the terminals mounted in mating connector 24. These raised bosses are effective to increase the positive forces of engagement between the mating terminals of the respective connectors and enhance the rigidity of the terminal. However, it should be understood that the invention is applicable for other types of terminals which may not include such raised bosses, but which have defined and determinable contact areas which, preferably, should not be disturbed during trimming of the terminals.

FIG. 9 shows one of the conventional terminals 46 after the terminal has been stamped and formed as described above in relation to FIGS. 7 and 8, and with the terminal further formed for insertion into dielectric housing 35 (FIG. 5). In other words, the final shape of the terminal in FIG. 9 corresponds to that shown in FIG. 5. Either before or after the terminal is so formed, web 60 and carrier strip 62 (FIG. 7) are severed from the terminal along line 72 (FIG. 7). Therefore, a drive shoulder is formed at line 72 to facilitate insertion of the terminal into its respective terminal-receiving passage in housing 35.

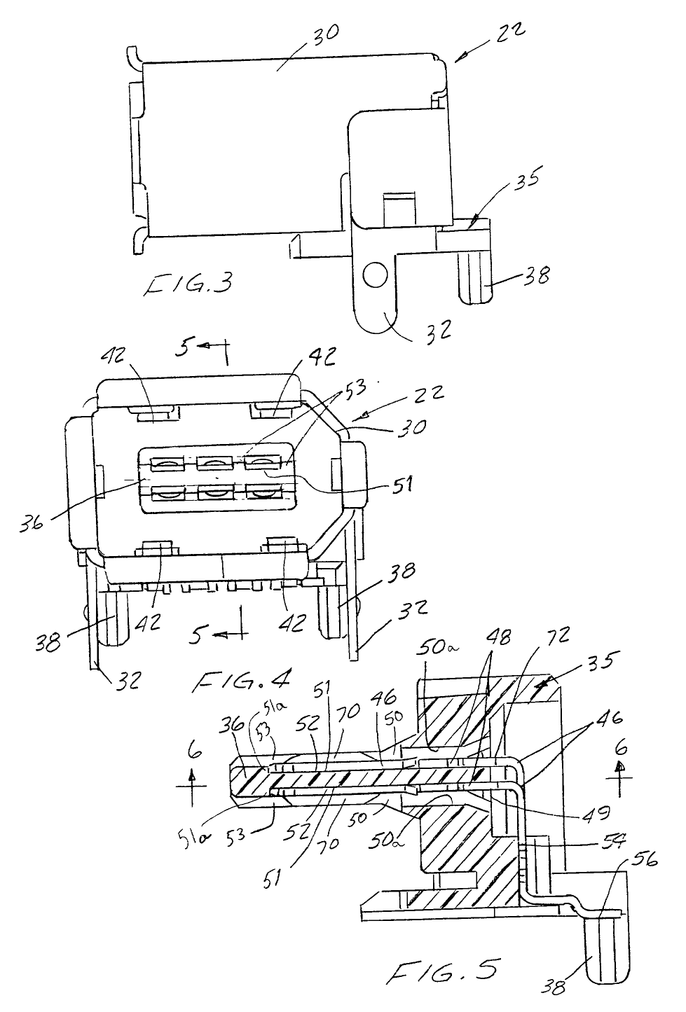

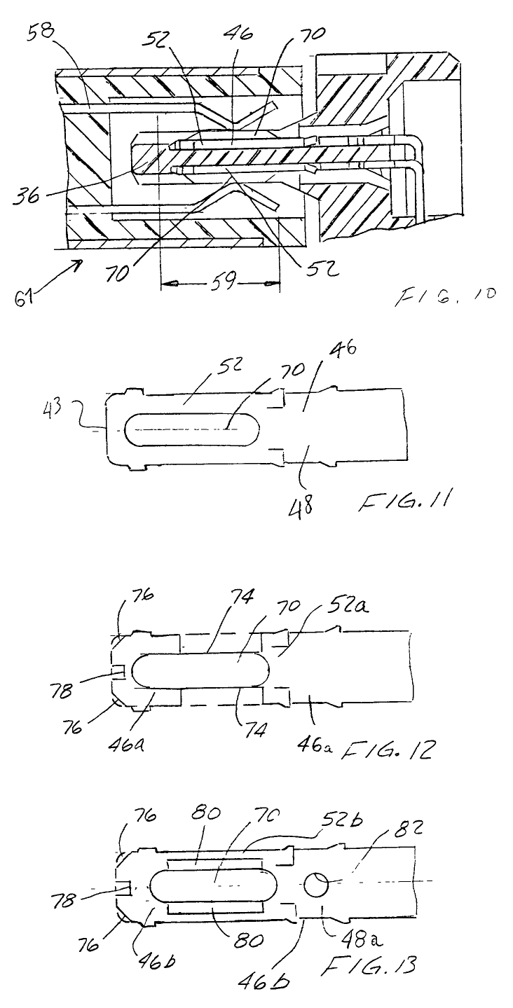

FIG. 10 shows a contacting interface area 59 at which contact portions 52 of conventional terminals 46 mate with terminals 58 of the complementary mating connector 24. The mating of terminal 46 and terminal 58 comprise a completed mated terminal pair 61. FIG. 4 illustrates that the terminals 46 are mounted on the top surface of the insert 35 and the terminals 46 are mounted on the bottom surface of the insert 35. Contact portions 52 of pairs of terminals 46 oppose each other on top and bottom surfaces of the insert 35. Because the pairs of contact portions 52 have relatively large plate areas opposed to each other in close proximity and are separated by a dielectric they increase the capacitance of the terminals 46 at the contact portions 52. The increased capacitance results in an impedance drop from the average impedance of the terminal 46 which increases the range of deviation of impedance across the terminal. This phenomena is shown in the impedance curve in FIG. 22 wherein the dip at Zₘᵢₙ represents the impedance at the contact portion 52. Conversely, the tail portion 54 has relatively small plate area of metal opposed to an adjacent tail portion 54 and a greater inductance and, therefore, a greater impedance, represented by the hump at Zₘₐₓ.

FIG. 11 shows a conventional contact portion 52, including a contact area 70, without any trimming and corresponding to the depiction of FIG. 7. FIGS. 12-20 show terminals of the present invention which have a similar configuration as the conventional terminal 46 but further modified to adjust the impedance across the contact portion 52 in accordance with the present invention. FIGS. 12-16 show various schemes for trimming contact portions 52a-52e of the terminals to effectively reduce the plate area of the contact portions to achieve a desired impedance across the contact portion or to minimize the impedance drop at the contact portion 52. The portions removed are shown in phantom in the Figures.

FIG. 12 shows one scheme for reducing the plate area of the contact portion 52a to reduce the capacitance and increase the impedance at the contact portion 52a. Specifically, side sections 74 of contact portion 52a of terminal 46a have been removed all the way to the contact area 70. In addition, corner sections 76 at the distal or insertion end of the contact portion have been removed. Still further, a central section 78 has been removed at the distal end of the contact portion. As a result, a significant area of contact portion 52a has been removed or trimmed away to significantly reduce the overall plate area of the contact portion 52. It should be noted that contact area 70 which engages the mating terminal is undisturbed. Metal may be removed as necessary to obtain a desired impedance at the contact portion 52a while preserving adequate provision for mechanical functions such as terminal retention, contacting engagement and robustness. Some of these considerations may not be as important if the terminals 46 are insert-molded in the housing 35. Additionally, the hump in the contact area 70 lends robustness to the terminal 26 and enhances the interengagement of the contact with the mating terminal 58. It is contemplated that these sections 74, 76, 78 will be removed from the contact portion 52 during the initial stamping process. However, the removal of these sections 74, 76, 78 may be performed later in the construction of the terminal.

FIG. 13 shows another scheme of trimming contact portion 52b by again removing corner sections 76 and central section 78 at the distal end of the contact portion. However, elongated holes 80 have been stamped out of the contact portion on opposite sides of contact area 70, and a round hole 82 has been stamped out of the body portion 48 at the inner end of contact area 70 of terminal 46b. Again, the result is the removal of significant metal plate area from the contact portion 52b to reduce the capacitance and, thereby, to increase the impedance of the terminals 46b at the contact portions 52b.

It should be noted that it is not necessary to remove metal from both sides of the contact area 70, so that the terminal 46 remains longitudinally symmetrical. Sections of the contact portion 52 may be selectively removed from only one side of the contact area 70 to obtain desired electrical characteristics with respect to adjacent mated terminal pairs.

FIG. 14 shows an additional scheme for reducing the area of terminal 46c. Side sections 74a of the contact portion 52c have been removed all the way to the front end of the terminal 46c. Skiving teeth 64a are disposed on the narrowed front end of the contact portion 52c.

FIG. 15 shows a further scheme for reducing the area of terminal 46d. Side sections 74b of the entire contact portion 52d and the body portion 48b have been removed. The elongated raised boss 70a of the contact area is lengthened to provide additional structural rigidity to the thinner terminal 46d. In addition to skiving teeth 64a disposed on the front end of the narrowed contact portions 52d, skiving teeth 66a are also disposed on the narrowed contact portion 46d.

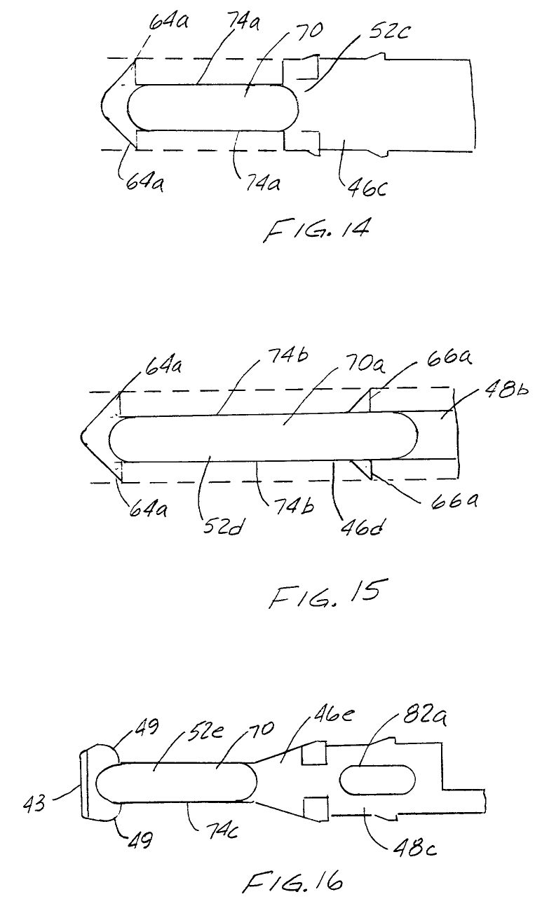

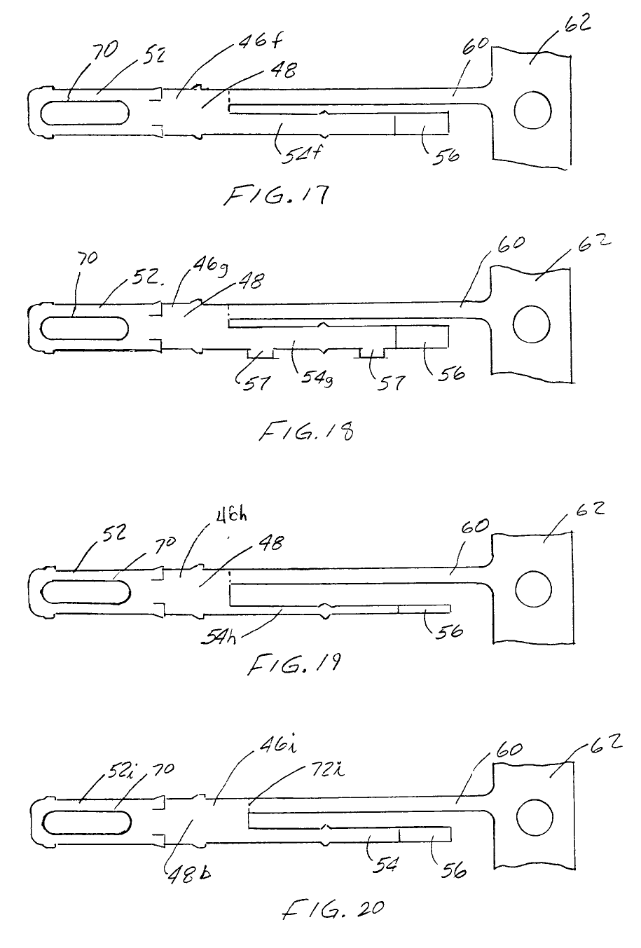

FIG. 16 shows a further scheme for reducing the area of the terminal 46e. Side sections 74c of contact portion 52e have been removed to define opposite, side recessed sections 74c bounded by front and rear edges. The rear edges rearwardly diverge at angles on opposite sides of the terminal 46e. Moreover, elongated hole 82a is fashioned in body portion 48c. It may be preferable to trim sections to have radiused corners 49 as shown in FIG. 16 to reduce electromagnetic field concentration points.

When the terminals 46a-46e are mounted in terminal cavities, the first edge 55a of the terminal 46 is disposed at the first lateral wall 53 of the cavity 50 and the second edge 55b of the terminal 46 is disposed at the second lateral wall 53 of the cavity 50. A gap in the contact portions 52a-52e of terminals 46a-46e is provided between an edge of the terminal at the boundary of the recessed section and the adjacent first and second lateral walls to expose a portion of the floor 51 of the terminal cavity 50 where a section of the contact portion 52a-52e has been trimmed away.

FIGS. 17-20 show another scheme for varying the impedance of terminals 46f-46i. In FIG. 17, tail portion 54f of the terminal 46f has been made wider than tail portion 54 shown in FIG. 7. Increasing the tail width decreases the impedance of the terminal and also reduces the extent of the impedance deviation from the contact portion 52. FIG. 18 shows an additional way to increase the plate area of the tail portion 54g in terminal 46g by adding sections 57 of metal to the edges thereof.

Conversely, tail portion 54h of terminal 46h in FIG. 19 has been made more narrow than tail portion 54 in FIG. 7. Reducing the plate area of the tail portion increases the impedance of the terminal and will increase the deviation of the impedance from the characteristic impedance at the contact portion. By narrowing and widening the tail portions, the plate areas of the tail portions can be varied to correspondingly adjust the impedance of the terminals.

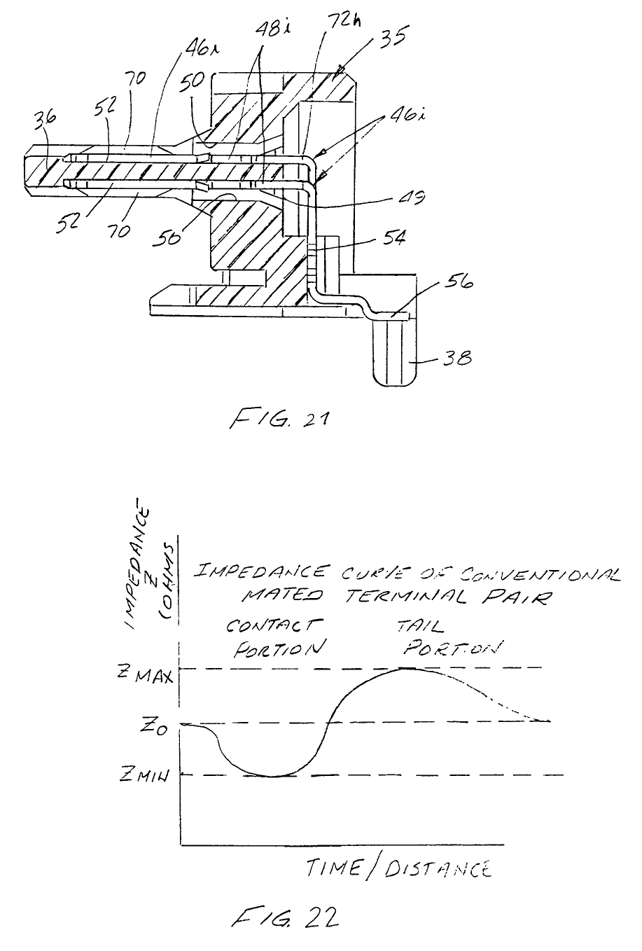

Finally, FIG. 20 shows a terminal 46i in which the drive shoulder 72i has been moved rearwardly (to the right) versus the location of drive shoulder 72i in FIG. 7. This increases the plate area of the contact portion 52i at the body portion 48i which, in turn, again will decrease the impedance of the respective terminals. In other words, the axial location of drive shoulder 72i can be varied to, correspondingly, adjust the metal plate area of the contact portion and the plate area distribution of the terminal to adjust the impedance of the terminal and the deviation of the impedance at the contact portion 52. FIG. 21 shows terminal 46i mounted in the housing 35 with the drive shoulder 72i spaced remotely from the mouth 49 of the terminal-receiving passage 50 as compared to terminal 46 in FIG. 5.

It will be understood that the invention may be embodied in other specific forms without departing from the spirit or central characteristics thereof. The present examples and embodiments, therefore, are to be considered in all respects as illustrative and not restrictive, and the invention is not to be limited to the details given herein.

1. A method of manufacturing an electrical connector to have a desired impedance, comprising the steps of:
providing a dielectric housing for mounting a plurality of terminals, each of said terminals having a contact portion at one end and a terminating portion at an opposite end;
determining a desired impedance for each of said plurality of terminals at a contact portion of each of said terminals;
determining a contact area of said contact portion which engages the respective mating terminal of the complementary mating connecting device;
shaping said plurality of terminals from sheet metal material;
selectively trimming said contact portion, except for said contact area, to a given size to vary a plate area of said contact portion according to said determination of the desired impedance of the terminals; and
mounting said terminals in said housing.

2. The method of claim 1 wherein said contact area of each terminal is generally centrally located between side edges of the contact portion, and the side edges of the contact portion are trimmed during said trimming step.

3. The method of claim 1 wherein said contact area of each terminal is generally centrally located in the contact portion of the terminal, and apertures are formed in the contact portion on opposite sides of the contact area during said trimming step.

4. The method of claim 1 wherein said contact portion defines a front end of the terminal, and the front end is trimmed during said trimming step.

5. The method of claim 1 wherein said terminals are shaped by stamping the terminals from the sheet metal material.

6. The method of claim 5 wherein said contact portion is trimmed during the stamping of the terminals.

7. The method of claim 1 wherein said contact portions comprise a planar blade defined by a forward end, two lateral sides and a rear end, said blade including a pair of opposing barbs on said lateral sides near the front end and a pair of opposing barbs on said lateral sides near the rear end.

8. A method of manufacturing an electrical connector to have a desired impedance comprising the steps of:
providing a dielectric housing for mounting a plurality of terminals, each of said plurality of terminals to be elongated and include a contact portion at one end and a tail portion at an opposite end;
shaping said plurality of terminals from sheet metal material;
selectively trimming one of said contact portion and said tail portion to a given size to vary a plate area thereof to adjust the impedance for each of said terminals; and
mounting each of said terminals in the housing;
whereby each of said plurality of terminals provide an adjusted impedance.

9. The method of claim 8 wherein said terminals are shaped by stamping the terminals from the sheet metal material.

10. The method of claim 8 wherein said terminals are shaped to be elongated and to have contact portions and tail portions of different widths.

11. A method of manufacturing an electrical connector to have a desired impedance, comprising the steps of:
providing a dielectric housing having a plurality of terminal-receiving passages for receiving a plurality of terminals, each of said terminals including a contact portion at a front end of said terminal and a tail portion at an opposite end of said terminal, said contact portion being larger than said tail portion defining a drive shoulder therebetween to facilitate inserting said terminals into respective ones of said terminal-receiving passages;
determining a desired impedance for each of a plurality of terminals;
shaping said plurality of terminals from sheet metal material;
selectively locating said drive shoulder at a given position to vary the relative plate areas of said contact portion and said tail portion according to the determination of the desired impedance of the terminals; and
inserting the terminals into the terminal-receiving passages of the housing;
whereby each of said terminals provide the desired impedance along the length of each of said terminals.

12. An impedance tuned electrical connector, comprising:
a dielectric housing;
a plurality of terminals mounted in said housing, each of said terminals including a contact portion at one end and a terminating portion at an opposite end, and said contact portion having a contact area for engaging a mating terminal of a complementary mating connecting device; and
at least one section selectively trimmed from said contact portion, except for said contact area, to provide the contact portion with a given plate area to adjust the impedance of the terminals.

13. The connector of claim 12 wherein said contact area of each terminal is generally centrally located between side edges of the contact portion, and said trimmed sections are located at the side edges.

14. The connector of claim 12 wherein said contact area of each terminal is generally centrally located in the contact portion of the terminal, and said trimmed sections are located on opposite sides of the contact area.

15. The connector of claim 12 wherein said terminals are mounted in terminal cavities in said housing, said terminal cavities including first and second lateral walls and a floor extending below the first and second laterals walls, said terminals having a first edge disposed at the first lateral wall and a second edge disposed at a second lateral wall, said terminal including a gap therein between said first and second lateral walls where said section has been trimmed from said contact portion.

16. An impedance tuned electrical connector, comprising:
a dielectric housing having a plurality of terminal-receiving passages; and
a plurality of terminals mounted in said terminal-receiving passages of said housing, each terminal including a contact portion at an insertion end of the terminal and a tail portion at an opposite end of the terminal, the contact portion being larger than the tail portion thereby defining a drive shoulder therebetween to facilitate inserting the terminal into its respective terminal-receiving passage, the drive shoulder being at a given location determined to vary the relative plate areas of the contact portion and the tail portion to adjust the impedance of the terminal.

17. The impedance tuned electrical connector of claim 16 wherein said dielectric housing includes a mouth for receiving said terminals therethrough and said drive shoulder being spaced remotely from said mouth.

18. An impedance tuned electrical connector, comprising.
a dielectric housing;
a plurality of terminals mounted in said housing, each terminal including a contact portion at one end and a terminating portion at an opposite end, and the contact portion having a contact area for engaging a mating terminal of a complementary mating connecting device;
said contact portion comprising a planar blade defined by a forward end, two lateral sides and a rear end, said blade including opposing barbs on said lateral sides; and
at least one section selectively trimmed from said contact portion, except for said contact area, to provide the contact portion with a given plate area to adjust the impedance of the terminals.

19. The impedance tuned electrical connector of claim 18 wherein said tail portion of each said terminal is substantially perpendicular to said contact portion.

20. The impedance tuned electrical connector of claim 18 wherein said housing includes a projecting portion with a series of terminal passages each having a bottom wall and lateral side walls and contact portions of said terminals retained in passages being exposed between said lateral side walls.

21. An impedance tuned electrical connector, comprising:
a dielectric housing;
a plurality of terminals mounted in said housing, each terminal including a contact portion at one end and a terminating portion, and the contact portion having a contact area for engaging a mating terminal of a complementary mating connecting device; and
at least one lateral side edge of the contact portion lateral to the contact area being trimmed to provide the contact portion with a given plate area to increase the average impedance of each terminal.

22. The connector of claim 21 wherein opposite side edges of the contact portion lateral to opposite sides of the contact area are trimmed to provide the contact portion with a given plate area to increase the average impedance of each terminal.

23. An impedance tuned electrical connector, comprising:
a dielectric housing;
a plurality of terminals mounted in said housing, each terminal including a contact portion at one end, a terminating portion at an opposite end and a retention portion between the contact portion and the terminating portion, the retention portion being wider than the terminating portion, and the contact portion having a contact area for engaging a mating terminal of a complementary mating connecting device; and
said retention portion being trimmed to provide the retention portion with a given plate area to increase the average impedance of each terminal.

24. The connector of claim 23 wherein said retention portion includes a trimmed hole of a predetermined size, with all of the material within the hole being removed from the terminal.

25. An impedance tuned electrical connector, comprising:
a dielectric housing;
a plurality of terminals mounted in said housing, each terminal includes a contact portion at one end and a terminating portion at an opposite end, the contact portion being wider than the terminating portion, and the contact portion having a forward tip and a contact area rearwardly of the tip for engaging a mating terminal of a complementary mating connecting device; and
said forward tip of the contact portion being trimmed to provide the contact portion with a given plate area to increase the average impedance of each terminal.

26. The connector of claim 25 wherein said forward tip of the contact portion is generally squared with the corners thereof trimmed.

27. The connector of claim 25 wherein said forward tip has a trimmed cutout in a forward edge thereof.

28. An impedance tuned electrical connector, comprising:
a dielectric housing;
a plurality of terminals mounted in said housing, each terminal including a contact portion at one end and a terminating portion at an opposite end, the contact portion being wider than the terminating portion, and the contact portion having a contact area for engaging a mating terminal of a complementary mating connecting device; and
opposite lateral side edges of the contact portion being trimmed outside the contact area to provide the contact portion with a given plate area to increase the average impedance of the terminals, the trimmed edges defining opposite side recessed sections bounded by front and rear edges, and the rear edges of the recessed sections being at rearwardly, mutually diverging angles on opposite sides of the terminal.

29. The connector of claim 28 wherein the front edges of said recessed areas are rounded.

30. An impedance tuned electrical connector, comprising:
a dielectric housing;
a plurality of terminals mounted in said housing, each terminal including a contact portion at one end and a terminating portion at an opposite end, the contact portion being wider than the terminating portion; and
the terminating portion including at least one protuberance of a given area to reduce the average impedance of the each terminal.

31. The connector of claim 30 wherein said terminating portion comprises an elongated tail of generally uniform width and said protuberance projects outwardly from one side of the tail.

32. The connector of claim 31, including a plurality of said protuberances spaced longitudinally of the tail.
